(19) United States
(12) Patent Application Publication
(10) Pub. No.: US 2025/0014964 A1
(43) Pub. Date: Jan. 9, 2025

(54) HYBRID BOND SHEET AND COOLED SEMICONDUCTOR POWER MODULE

(71) Applicant: Huawei Digital Power Technologies Co., Ltd., Shenzhen (CN)

(72) Inventors: Andreas MUNDING, Nuremberg (DE); Yumin Liu, Shanghai (CN); Lasse Petteri Palm, Nuremberg (DE)

(73) Assignee: Huawei Digital Power Technologies Co., Ltd., Shenzhen (CN)

(21) Appl. No.: 18/891,135

(22) Filed: Sep. 20, 2024

Related U.S. Application Data
(63) Continuation of application No. PCT/CN2022/136929, filed on Dec. 6, 2022.

(30) Foreign Application Priority Data
Mar. 22, 2022 (WO) PCT/EP2022/057489

(51) Int. Cl. H01L 23/373; H01L 21/48; H01L 23/00; H01L 23/31

(52) U.S. Cl. CPC H01L 23/3735; H01L 21/4882; H01L 23/3737; H01L 24/32; H01L 23/3107; H01L 2224/32225

(57) ABSTRACT

A hybrid bond sheet for mounting a semiconductor power module to a heat sink includes a thermally conductive core layer having an upper main face and a lower main face; a first bond layer formed at the upper main face of the core layer for bonding the hybrid bond sheet to a semiconductor power module; and a second bond layer formed at the lower main face of the core layer for bonding the hybrid bond sheet to a heat sink; where the core layer is subdivided into a plurality of core metal sections and core polymer sections which are formed side-by-side between the upper main face and the lower main face, the subdivided core metal sections being configured to enable a uniform heat transfer between the semiconductor power module and the heat sink and to reduce thermal stress at interfaces between the hybrid bond sheet and the heat sink.

### CROSS-REFERENCE TO RELATED APPLICATION

This application is a continuation of International Application No. PCT/CN2022/136929, filed on Dec. 6, 2022, which claims priority to International Patent Application No. PCT/EP2022/057489, filed on Mar. 22, 2022. The disclosures of the aforementioned applications are hereby incorporated by reference in their entireties.

### TECHNICAL FIELD

The embodiments relate to the field of power products and production methods thereof. Various embodiments relate to a hybrid bond sheet and a cooled semiconductor power module including such hybrid bond sheet and corresponding methods for manufacturing these devices. The embodiments further relate to a semiconductor power entity produced by hybrid bonding. For example, thermal management of a power electronic entity using hybrid bond sheets is provided.

### BACKGROUND

The thermal interface of power modules is electrically isolated against the high operating voltage by the module internal ceramic substrate. In order to increase performance and manufacturability, thermal interface materials (TIM) are applied. Thermal mismatch, large area interfaces and unbalanced vertical package structures cause high levels of stress in the TIM which can introduce strong warpage at room temperature or during a thermal cycle. It can accelerate fatigue-based failure mechanisms at the thermal interface and can be the root cause for limited module lifetime. The performance and the lifetime of such modules is limited by high junction temperatures of the chip. It is therefore desirable to narrow the junction temperature distribution within a module. The possibilities to achieve this by design on a substrate level are limited because in some embodiments only one routing layer, and possibly a wire bond layer or a clip layer is available for interconnecting the chips. These limited resources are primarily used for solving the main functional constraints such as isolation clearance, parasitic impedance, interconnect technology, gate signal integrity, etc. This practice leaves no or little degrees of freedom for thermal optimization and homogenization of junction temperature across the module. As consequence, a large potential to increase performance and reliability of power modules remains unused.

### SUMMARY

The embodiments provide a power module with reduced junction temperature, such as a solution for a thermally optimized power module based on homogenization of junction temperature across the module.

The foregoing and other objects are achieved by the features of the embodiments and the related description and the figures.

The solution is achieved by using a specially designed easily applicable hybrid bond sheet for thermal management which has metallic and dielectric bond materials as TIM on it and which can be patterned/structured easily by available PCB manufacturing equipment. The sheets can be permanently laminated between power module and heatsink/cooler using moderate temperature and pressure (e.g., for a target of 170° C. to 200° C., 1 MPa to 5 MPa).

The pattern can be designed such that it enables compensation of temperature non-uniformity of semiconductors in a module by local variation of thermal conductivity and control of heat flow. This can help to operate power modules closer to their absolute capability limit since the maximum current of a module can be defined by the chip with the highest temperature.

The presented solution offers a cost competitive alternative to prior art high performance conductive TIM solutions like for example vertical graphite sheets or large area solder layers or sinter layers.

Points of the presented solutions can be summarized as follows: the TIM is a hybrid bond sheet and permanently applied by temperature and pressure. The metallic surface of the bond sheet is divided into islands by a dielectric grid or mesh pattern. The bond sheet has a direct metal connection from top to bottom underneath the metal islands. The dielectric grid takes the function of a sealing, protection, stress buffer, and crack stop. The metallic island areas take the function of main heat conductor. The two bond mechanisms (metallic & dielectric) provide redundancy and increased reliability. The pattern can be designed to compensate chip temperature non-uniformity during operation. The sheets can be produced with economic benefit using standard PCB manufacturing equipment.

Embodiments can be applied for power modules, e.g., automotive traction inverter; industrial, PV inverter, with an exemplary thermal interface area above 50 mm×50 mm.

Embodiments are applicable to power modules where temperature and pressure can be applied during manufacturing.

Embodiments relate to the thermal integration of power modules into the heat extraction path of a power electronic system. In some embodiments, the thermal interface of such modules is already electrically isolated against the high operating voltage by the module internal ceramic substrate. Embodiments overcome the above-described disadvantages and limitations of thermal interface materials (TIM). Embodiments can be applied for improved thermal management of single side cooled (SSC) and dual side cooled (DSC) and other types of power modules.

Embodiments solve warpage and long-term reliability issues of solder or sinter based metallic TIM (thermal interface materials) thermal interfaces of high-power modules that may be applied for automotive or industrial applications.

Embodiments reduce thermal mismatch and stress in large area interfaces and unbalanced vertical package structures to avoid warpage at room temperature or during a thermal cycle.

Embodiments significantly reduce fatigue-based failure mechanisms at the thermal interface and can thus increase the module lifetime.

Embodiments compensate chip temperature non-uniformity within operational power modules and hence increase performance and lifetime by reducing the junction temperature distribution within a module. For example, the solutions include a mechanism for thermal optimization and homogenization of junction temperature across the module. As a consequence, performance and reliability of power modules can be increased.

This embodiments also present a solution for a semiconductor power entity that has improved thermal characteristics and provides low parasitic interconnection paths.

The above solution achieves the above-described objects at a desirable cost by the combination of vertical system integration (3rd dimension), panel level packaging and low temperature metal joining (e. g. diffusion soldering or sintering). By the combination of these technologies, at least the following advantages can be realized:

Vertical system integration (3D-integration) drastically shortens interconnect length and allows to significantly increase the power density. According to the embodiments, this technology can be used in an industrialized scale for chip embedding or other panel level packaging technologies and for power device packaging.

Hybrid bonding according to the embodiments is a process that allows simultaneously bonding of metallic contacts & dielectric areas in one bonding process. Hybrid bonding can be used for 3D-integration on wafer level. In some examples, a direct surface activated bonding (SAB) process is used, which may require specialized high vacuum equipment and tight control of surface quality with a roughness in the range of about 1 nm, for example. This makes hybrid bonding in its current form unsuitable for power electronics packaging. The embodiments present a mechanism to make this technology available for panel level hybrid bonding process for power electronics packaging.

Chip embedding according to the embodiments employs PCB (printed circuit board) materials interfacing directly with the semiconductor die. In addition to excellent electrical and thermal performance, chip embedding offers at least the benefits of panel scale mass production. Currently, CE, which is still new technology, is not yet used for 3D stacking. It could be used but due to limitations, e.g., direct vertical connections, it is not yet used (only one core layer, e.g. laminate layer).

According to the embodiments vertical connections can be implemented between pre-manufactured PCB layers, resulting in a connection layer that embeds large connection metal areas in isolation material, achieving sufficient current carrying capability and thermal conductivity for power electronics.

The embodiments are based on the concept where direct vertical connections can be made between two or more laminate core layers, also referred to as laminate layers or core layers, where the vertical connections have the following characteristics: they can be made within the projected physical outline of embedded components; they are not confined to a certain shape (e. g. round) or size (e. g. 100 μm diameter); they do not need an outer layer plating process to form the electrical connection; they are suitable for power electronics (have low inductance and high current capability); they are reliable and do not remelt at bond temperature; they can be formed either by diffusion soldering or sintering.

A method or process to form these vertical connections has the following characteristics: using a standard PCB lamination process (bond temperature, pressure, format); using hybrid bonding to bond metal to metal and dielectric to dielectric in one step; several premanufactured layers can be connected to each other in one lamination step or in several sequential lamination steps; the bonding materials can be attached or applied to the surface of the laminate layers or placed between the laminate layers prior to bonding.

In case of diffusion soldering, the vertical metal-to-metal connection can be based on the formation of intermetallic phases in a selected bi- or multi metal system. The structure can have a minimum of three layers that contain at least one metal or metal alloy layer that has a low melting point and which is located between two separate metal layers that have a high melting point.

Some low melting point metals that can be used are e.g., tin (Sn) and indium (In) and the high melting point metal or top metal layers are e.g., copper (Cu), gold (Au) and silver (Ag). In diffusion soldering the two high melting point metal layers can be bonded together by aim of at least one low temperature melting metal layer. During the bonding the layer can be pressed against each other and the temperature can be increased above the eutectic point for the selected metal system. Because the temperature is above the eutectic point of the selected metal system a liquid phase can appear and the metals can start to inter-diffuse and create intermetallic compounds (IMCs). Because the formed inter-metallics have a higher melting point, those are gradually solidified. If the bonding time is long enough all low melting point metals react with the high melting point metals to form inter-metallics and the joint is completely solidified. The formed intermetallic compounds have a significantly higher melting point than the low melting point metals and the joint does not melt anymore at the bonding temperature.

The diffusion soldering process can be divided into five phases that are wetting, alloying, liquid diffusion, gradual solidification and solid diffusion. The suitable metal, metal alloy or paste on one or both laminate layers or between the laminate layers (with metal) can be applied by plating, printing, dispensing or other suitable methods. Diffusion soldering or sintering can be used, for example, to form the metallic interconnection.

The described semiconductor power entity can be described by the following features, that are: two or more laminate layers that i) are laminated together with isolating polymer layer; ii) have Cu metal routing at least on top and bottom side; iii) are electrically connected together with a non-re-meltable metal joint embedded in the isolating polymer layer.

Other features are as follows: all laminate layers are PCB core layer in panel level (up to normal PCB production sizes); at least one laminate layer has power components embedded inside; the first power die in the first laminate layer and the second power die in the second laminate layer can face in different directions, but are not limited to this, in some other applications they can also face in the same direction. In one example, the first power die in the first laminate layer and the second power die in the second laminate layer can be arranged in a half bridge configuration. It understands that a lot of other configurations of the two power dies can be implemented as well.

In order to describe the embodiments in detail, the following terms, abbreviations and notations will be used:
TIM thermal interface material
SSC single side cooled
DSC double side cooled
PCM phase change material
IGBT insulated gate bipolar transistor
FRD freewheeling diode
IMC intermetallic compound
DBC direct bonded copper (substrate)
CTE coefficient of thermal expansion
AR aspect ratio
PCB printed circuit board
SAB surface activated bonding
HDI high density interconnect
SLID solid liquid interdiffusion
TLP transient liquid phase
TLPB transient liquid phase bonding

Thermal resistance in K/W is describing the temperature difference a certain amount of dissipated power causes when its generated heat is flowing through a defined volume. In can be directly measured when temperatures along the thermal path and dissipated power are known.

Thermal conductivity in W/(m*K) is a physical material property describing how good a material can conduct heat in a certain direction or isotropically, if not otherwise specified. It is a thickness and geometry independent property describing the bulk material that does not consider the interfaces to other materials.

In-plane, through-plane describe the directional thermal conductivity in case the material has a non-isotropic thermal characteristics, like for example graphite sheets. In-plane means in x/y direction, or the directions parallel to the surface; through-plane means the direction orthogonal to the surface of the sheet material.

B-stage can refer to non-liquid uncured polymer material that has a predefined shape. It is stable enough to be handled in logistics and production, does not have a sticky surface, or has a surface protected by a liner that can be removed to activate the surface before bonding. B-stage material can be used for bonding, filling, lamination, gluing, attaching, etc. with minimum tooling effort because no liquids have to be handled.

Homologous temperature can be defined as the quotient between operating temperature and melting temperature in K. In can be used to describe the mechanical stability and plasticity of metals at certain use temperatures. For example, soft solder metals or low melting point metals at room temperature can have a homologous temperature above 0.6.

Prepreg can be described as PCB laminate B-stage material with a glass fiber matrix.

Hybrid bonding in the embodiments means (in addition to the definition given above) the simultaneous bonding of metallic and dielectric surfaces to form void-free positive connections between metals and metals, dielectrics and dielectrics, and between metals and dielectrics. The term refers to wafer level bonding, chip-level bonding, panel level bonding, but also—as described here—to discrete one-by-one power module to heatsink bonding.

Embodiments present a hybrid bond sheet having a metallic surface which is divided into islands separated by a dielectric grid or mesh pattern. The dielectric grid takes the function of a sealing, protection, stress buffer, and crack stop. The bond sheet has a direct metal connection from top to bottom underneath the metal islands. By that feature, heat can be effectively conducted away from the chip.

The two bond mechanisms: metallic and dielectric connection are presented, which provide redundancy and increased reliability.

The metal connection can be made by sintering, diffusion soldering or nano-wiring at temperatures below 200° C. which results in a non-remelting stable metal connection and hence resulting in a low homologous temperature.

The pattern can be designed to compensate chip temperature non-uniformity during operation. Thus, power modules can be operated closer to their absolute performance limit since the maximum current of a module can. be defined by the chip with the highest temperature.

Panel level PCB materials can be used. Thus, the hybrid bond sheets can be produced with economic benefit using standard PCB manufacturing equipment.

The embodiments relate to a hybrid bond sheet according to a first aspect, a cooled semiconductor power module according to a second aspect, a method for manufacturing a hybrid bond sheet according to a third aspect, a method for manufacturing a cooled semiconductor power entity according to a fourth aspect, a semiconductor power entity according to a fifth aspect, a method for producing such semiconductor power entity according to a sixth aspect, a computer program product according to a seventh aspect and a non-transitory computer-readable medium according to an eighth aspect, as described in the following.

According to the first aspect, the embodiments relate to a hybrid bond sheet for mounting a semiconductor power module to a heat sink, the hybrid bond sheet including: a thermally conductive core layer having an upper main face and a lower main face opposing the upper main face; a first bond layer formed at the upper main face of the core layer for bonding the hybrid bond sheet to a semiconductor power module; and a second bond layer formed at the lower main face of the core layer for bonding the hybrid bond sheet to a heat sink; where the core layer is subdivided into a plurality of core metal sections and core polymer sections which are formed side-by-side between the upper main face and the lower main face, the subdivided core metal sections being configured to enable a uniform heat transfer between the semiconductor power module and the heat sink and to reduce thermal stress at interfaces between the hybrid bond sheet and the heat sink.

Using such a hybrid bond sheet for mounting a semiconductor power module to a heat sink provides a power module with the advantages of reduced junction temperature. An advantage is at least achieved by using the hybrid bond sheet in order to provide a thermally optimized power module based on homogenization of junction temperature across the module.

Hybrid bond sheet means that bonding of the two joining members includes more than one (here: 2) bonding mechanisms, an electrically conductive metallurgical bond, and a dielectric, electrically isolating bond. The two bond mechanisms act in laterally separated partial areas of the bond sheet, which is brought in between the two joining partners.

The hybrid bond sheet is thus a bond sheet made of different material layers such as metals and dielectrics.

As already described above, hybrid bonding means the simultaneous bonding of metallic and dielectric surfaces to form void-free positive connections between metals and metals, dielectrics and dielectrics, and between metals and dielectrics. The term refers to wafer level bonding, chip-level bonding, panel level bonding, but also to discrete one-by-one power module to heatsink bonding.

The critical parameter here is thermal stress. When thermal stress is increasing, the power module may disconnect or delaminate from the heatsink.

The interfaces between the hybrid bond sheet and the heat sink can be the interfaces of the second bond layer, e.g. interfaces of the metal sections and the polymer sections of the second bond layer.

In an exemplary implementation of the hybrid bond sheet, the subdivided core polymer sections form a core polymer grid that is subdividing the core metal sections into core metal islands.

This provides at least the advantage that the core polymer grid takes the function of a sealing, protection, stress buffer and crack stop.

In an exemplary implementation of the hybrid bond sheet, the core polymer grid includes evenly shaped sections and/or unevenly shaped sections.

This provides at least the advantage that the core polymer grid can be designed to compensate chip temperature non-uniformity during operation.

In an exemplary implementation of the hybrid bond sheet, a size of the core metal islands is greater than a size of the core polymer grid.

This provides at least the advantage of improved thermal dissipation via the core metal islands.

In an exemplary implementation of the hybrid bond sheet, the plurality of core metal sections and core polymer sections are formed according to a heat dissipation pattern of the semiconductor power module.

This provides at least the advantage of enabling compensation of a non-uniform heat conduction between the semiconductor power module and the heat sink and also enabling compensation of non-uniform temperature distribution of power semiconductor chip junction temperature.

A uniform junction temperature of all power dies can thus be achieved, so that the switching behavior and lifetime consumption during operation is more uniform. Otherwise, the hottest device would shorten lifetime and worsen switching behavior of the overall module.

In an exemplary implementation of the hybrid bond sheet, the core layer includes at least one of the following areas: areas in which an area fraction of the core metal sections is higher than an area fraction of the core polymer sections; areas in which an area fraction of the core polymer sections is higher than an area fraction of the core metal sections; and areas in which an area fraction of the core metal sections is equal to an area fraction of the core polymer sections.

This provides at least the advantage of flexible design. The area fraction of the core metal sections specifies a merged area of all core metal sections versus an overall core layer interface area. The area fraction of the core polymer sections specifies a merged area of all core polymer sections versus an overall core layer interface area.

In an exemplary implementation of the hybrid bond sheet, the first bond layer is subdivided into a plurality of first bond metal sections and first bond polymer sections which are formed side-by-side on the upper main face of the core layer; and/or where the second bond layer is subdivided into a plurality of second bond metal sections and second bond polymer sections which are formed side-by-side at the lower main face of the core layer.

This provides at least the advantage of a flexible design, where the first bond metal sections and the first bond polymer sections can be arranged independently but also dependent on the core metal sections and the core polymer sections.

In an exemplary implementation of the hybrid bond sheet, the first bond layer is configured to provide a simultaneous bonding by the following two mechanisms: metallurgical bonding of the first bond metal sections to any metal; and gluing or encapsulating of the first bond polymer sections to form an insulating bond to any surface; and/or where the second bond layer is configured to provide a simultaneous bonding by the following two mechanisms: metallurgical bonding of the second bond metal sections to any metal; and gluing or encapsulating of the second bond polymer sections to form an insulating bond to any surface.

This provides at least the advantage of a simultaneous bonding using two different mechanism or techniques.

In an exemplary implementation of the hybrid bond sheet, a first bond interface formed by the first bond layer is designed to be free of channels, voids, gaps or unfilled spaces; and/or a second bond interface formed by the second bond layer is designed to be free of channels, voids, gaps or unfilled spaces.

This provides at least the advantage of a tight and strong bonding connection without voids, gaps or unfilled spaces.

In an exemplary implementation of the hybrid bond sheet, a material of the plurality of first bond metal sections is different or the same as a material of the core metal sections; and/or a material of the plurality of second bond metal sections is different or the same as a material of the core metal sections.

This provides at least the advantage of design flexibility. Each of the materials specified above, e.g. material of the bond metal sections and material of the core metal sections can be a metal or metal paste or semi metal (like carbon) with high thermal conductivity, that can also be electrically conductive and is not required to be electrically isolating, but is capable of forming a bond to the heatsink or to the power module.

In one example, the metallurgical bonding is by soldering and the core metal section has a plated solder finish, as does the first/second bond metal sections. Here, both materials can be the same.

In an exemplary implementation of the hybrid bond sheet, the first bond metal sections of the first bond layer are aligned with the core metal sections of the core layer; the first bond polymer sections of the first bond layer are aligned with the core polymer sections of the core layer; the second bond metal sections of the second bond layer are aligned with the core metal sections of the core layer; and/or the second bond polymer sections of the second bond layer are aligned with the core polymer sections of the core layer.

Or in other words: the core metal sections are following the pattern of the bond metal sections; and the core polymer sections are following the pattern of the bond polymer sections.

This provides at least the advantage of redundancy and increased reliability.

In an exemplary implementation of the hybrid bond sheet, the subdivision of the first bond metal sections and the first bond polymer sections forms a different pattern than the subdivision of the core metal sections and the core polymer sections; and/or the subdivision of the second bond metal sections and the second bond polymer sections forms a different pattern than the subdivision of the core metal sections and the core polymer sections.

The above features can be of advantage for the case where the core metal sections are merged into one continuous metal layer for heat conduction and spreading, but with higher risk of increased thermal stress due to large area accumulation of thermal expansion.

In an exemplary implementation of the hybrid bond sheet, the subdivided first bond polymer sections form a first polymer grid and the subdivided core polymer sections form a second polymer grid, where a width of the first polymer grid is different from a width of the second polymer grid.

This provides at least the advantage of redundancy and increased reliability.

In an exemplary implementation of the hybrid bond sheet, the first polymer grid is subdividing the first bond metal sections into metal islands; where the second polymer grid is subdividing the core metal sections into metal islands; where the metal islands formed by the second polymer grid are larger than the metal islands formed by the first polymer grid.

Or in other words, the subdivided metal sections are separated by polymer sections; and the subdivided core metal sections are separated by core polymer sections.

This provides at least the advantage of flexible heat dissipation, stress buffering and crack protection.

In an exemplary implementation of the hybrid bond sheet, the subdivided core metal sections form a core metal grid that is subdividing the core polymer sections into core polymer islands.

This provides at least the advantage that the core metal grid takes the function of a flexible heat dissipation.

In an exemplary implementation of the hybrid bond sheet, the metal grid formed by the subdivided core metal sections includes a leadframe.

This provides at least the advantage that the leadframe can be easily manufactured.

According to the second aspect, the embodiments relate to a cooled semiconductor power module, including: a semiconductor power module including: a thermally conductive substrate having a substrate upper main face and a substrate lower main face opposing the substrate upper main face; a semiconductor chip attached to the substrate upper main face; and a mold compound at least partially encapsulating the semiconductor chip; and a hybrid bond sheet according to the first aspect for bonding the semiconductor power module to a heat sink; where the first bond layer of the hybrid bond sheet is attached to the substrate lower main face forming a fully polymer encapsulated electrically and thermally conductive connection; and/or where the second bond layer of the hybrid bond sheet is attached to the heat sink forming another fully polymer encapsulated electrically and thermally conductive connection.

Such a cooled semiconductor power module provides at least the advantages of reduced junction temperature. This advantage is achieved by using the hybrid bond sheet in order to provide a thermally optimized power module based on homogenization of junction temperature across the module.

In an exemplary implementation of the cooled semiconductor power module, the cooled semiconductor module includes: the heat sink attached to the semiconductor power module; where interfaces formed by the fully polymer encapsulated electrically and thermally conductive connection of the first bond layer and/or the second bond layer are forming a non-remelting electrical and mechanical connection.

This provides at least the advantage of improved thermal and electrical characteristics.

In an exemplary implementation of the cooled semiconductor power module, interfaces formed by the fully polymer encapsulated electrically and thermally conductive connection of the first bond layer and/or the second bond layer are forming one of a diffusion soldering connection, a sintering connection, a force-fitted metal connection or a nano-wire connection.

These interfaces have at least the advantage of being designed for high current loads.

In an exemplary implementation of the cooled semiconductor power module, for the force-fitted metal connection, a contact force between the metal sections of the hybrid bond sheet and respective metal sections of the substrate and/or heat sink is initiated by the polymer sections which have a higher coefficient of thermal expansion than the metal sections.

That means, after the bonding a shrinking of the polymer sections is stronger than a shrinking of the metal sections which results in pressing the metal sections of hybrid bond sheet, substrate and heat sink against each other.

This provides at least the advantage of a stable force-fitted metal connection.

According to the third aspect, the embodiments relate to a method for manufacturing a hybrid bond sheet for mounting a semiconductor power module to a heat sink, the method including: forming a thermally conductive core layer having an upper main face and a lower main face opposing the upper main face; forming a first bond layer at the upper main face of the core layer for bonding the hybrid bond sheet to a semiconductor power module; and forming a second bond layer at the lower main face of the core layer for bonding the hybrid bond sheet to a heat sink; where the core layer is subdivided into a plurality of core metal sections and core polymer sections which are formed side-by-side between the upper main face and the lower main face, the subdivided core metal sections being configured to enable a uniform heat transfer between the semiconductor power module and the heat sink and to reduce thermal stress at interfaces between the hybrid bond sheet and the heat sink.

Such a method provides at least the advantage of an easy manufacturing of a hybrid bond sheet. Such a hybrid bond sheet has at least the advantages as described above.

According to the fourth aspect, the embodiments relate to a method for manufacturing a cooled semiconductor power entity, the method including: providing a semiconductor power module; providing a heat sink; placing a hybrid bond sheet according to the first aspect between the semiconductor power entity and the heat sink; thermally pressing the semiconductor power module and the heat sink against each other to activate the first bond layer and the second bond layer of the hybrid bond sheet and to form bond connections between the semiconductor power module and the heat sink.

Such a method provides at least the advantage of an easy manufacturing of a cooled semiconductor power entity. Such a cooled semiconductor power entity has at least the advantages as described above.

According to the fifth aspect, the embodiments relate to a semiconductor power entity, including: a first laminate layer having a first laminate upper main face and a first laminate lower main face opposing the first laminate upper main face; a second laminate layer having a second laminate upper main face and a second laminate lower main face opposing the second laminate upper main face; an isolation layer arranged between the first laminate layer and the second laminate layer; a first metal layer arranged at the first laminate upper main face of the first laminate layer and a second metal layer arranged at the first laminate lower main face of the first laminate layer; a third metal layer arranged at the second laminate upper main face of the second laminate layer and a fourth metal layer arranged at the second laminate lower main face of the second laminate layer; and a connection metal layer embedded in the isolation layer between the first laminate layer and the second laminate layer, the connection metal layer forming an electrical connection with the second metal layer and the third metal layer.

Such a semiconductor power entity provides at least the advantage of having direct vertical connections between two or more laminate core layers. These vertical connections can be made within the projected physical outline of embedded components if the laminate layer have such embedded components; they are not confined to a certain shape or size, e.g. they can be flexible designed in shape and size; they do not need an outer layer plating process to form the electrical connection; they are suitable for power electronics, since they have low inductance and high current capability; they are reliable and do not remelt at bond temperature. These vertical connections can be formed, for example by solid-liquid interdiffusion (SLID), transient liquid phase (TLP) bonding or sintering.

Thus, the semiconductor power entity provides increased power density and efficiency, short, current-capable low-parasitic interconnection paths, a very good thermal management and improved electrical isolation. Conductor traces with a current capability of several ten Amperes up to hundreds of Amperes and even higher, and power modules with an internal stray inductance below about 10 nH and even lower can be achieved.

The first, second, third and fourth metal layers can be redistribution or routing metal layers for redistributing or routing current paths. It can be understood that the semiconductor power entity is not restricted to these four metal layers and two laminate layers as exemplarily shown in the Figures. The semiconductor power entity can also have more layers. The layers that are laminated may also be the layers of a multi-layer board, e.g., four layers or six layers, instead of the two-layer boards that are shown here in the Figures which are only examples for such a multi-layer board.

The semiconductor power entity can also be referred to as semiconductor power product. Such product can also be a module or a larger size product (PCB), for example, where the power components may be embedded inside the PCB and the rest of the components may be placed on top. Some or all of the passives may also be embedded in the PCB, depending on the passive components, e.g., depending on a type of the passive components.

In an exemplary implementation of the semiconductor power entity, the connection metal layer forms a non-remelting electrical and mechanical connection.

Such a “non-remelting” connection is different from a normal solder connection such as formed during a conventional TC/NCP process (thermo-compression bonding with solder and pre-applied non-conductive polymer). A non-remelting connection provides at least the advantage that it is a connection which will not remelt or decompose at temperatures much higher than the process temperature it was formed.

In an exemplary implementation of the semiconductor power entity, the connection metal layer forms one of a diffusion soldering connection or a sintering connection.

Diffusion soldering or diffusion bonding is a metal joining technique which can be advantageously applied to electronic packaging. It operates on the principle of interdiffusion of two dissimilar metals, where a liquid phase is completely transformed into solid state by metallic phase reactions and intermetallic compound formation. Similar terms for such technique are transient liquid phase bonding, solid-liquid interdiffusion, isothermal solidification. The technique provides at least the advantage that the resulting solid phase has a higher melting point than the temperature of the formation process.

Sintering is the process of compacting and forming a solid mass of material by heat or pressure without melting it to the point of liquefaction. Sintering happens as part of a manufacturing process used with metals, ceramics, plastics, and other materials. The atoms in the materials diffuse across the boundaries of the particles, fusing the particles together and creating one solid piece. An advantage of sintering is at least the following: because the sintering temperature does not have to reach the melting point of the material, sintering is often chosen as the shaping process for materials with extremely high melting points.

The connection metal can form a composed metal layer, for example. Such composed metal layer may include a compound from more than two metals, e.g., such as inter-metallic layer, or a connection of metal layers including one single metal, or a connection of a metal and a polymer or polymer mixture.

For such inter-metallic layer, the melting point of the inter metallic layer is higher than the lamination/process temperature where it was formed.

The connection metal layer may include more than 80% metal and less than 20% pores or polymers, for example.

The connection metal layer is designed for high current loads.

In one embodiment, the inter-metallic layer may have a minimum lateral size of >1 mm in each dimension, but not smaller than 0.1 mm.

The intermetallic layer may have a large cross-section, short length and good conductor and due to that is suitable for high current loads.

In one embodiment, the connection metal layer may have a thickness of 5 to 50 μm, but not thicker than 0.2 mm (in case of a single layer structure).

In an exemplary implementation of the semiconductor power entity, the first laminate layer is embedding a first power semiconductor; and/or the second laminate layer is embedding a second power semiconductor.

Such a semiconductor power entity provides at least the advantage of increased power density and efficiency, short, current-capable low-parasitic interconnection paths, a very good thermal management and improved electrical isolation. Conductor traces with a high current capability of e.g., several ten amperes up to hundreds of amperes, and power modules with an internal stray inductance, e.g. below about 10 nH can be implemented.

When defining a first power semiconductor and a second power semiconductor, this does not exclude that more than one first power semiconductor can be embedded in the first laminate layer and more than one second power semiconductor can be embedded in the second laminate layer.

In an exemplary implementation of the semiconductor power entity, the connection metal layer vertically connects the second metal layer with the third metal layer providing a vertical electrical connection for the first power semiconductor and the second power semiconductor.

This provides at least the advantage that a shortest-path electrically connection can be realized which reduces stray inductance of the power entity and impedance between the two metal layers.

In an exemplary implementation of the semiconductor power entity, the connection metal layer forms a direct electrical connection path between the first power semiconductor and the second power semiconductor without a detour via through-hole vias arranged laterally to the two power semiconductors.

As described above, such a direct electrical connection path provides at least the advantage of shortest-path large area electrical connection between the two metal layers, reducing impedance and stray inductance.

In an exemplary implementation of the semiconductor power entity, the second metal layer and/or the third metal layer includes at least one of copper, gold, silver, palladium or nickel or a combination thereof; where in case of a diffusion soldering connection, the connection metal layer includes any suitable low temperature melting metal like for example tin and indium in combination with any of the metals of the second metal layer or the third metal layer or an alloy thereof; where in case of a sintering connection, the connection metal layer includes a porous layer of silver or copper or other suitable sintering metal with optional polymer filling.

This provides at least the advantage that a lot of metals and metal alloys or combinations thereof with different characteristics can be applied

Note that such connection metal layer includes also the following combination: (tin OR indium OR (tin AND indium)) in combination with any of the metals of the second metal layer or the third metal layer or an alloy thereof.

In an exemplary implementation of the semiconductor power entity, the first power semiconductor and the second power semiconductor are configured to form a half bridge configuration. It understands that a lot of other configurations of the two power semiconductors can be implemented as well.

This provides at least the advantage that the semiconductor power entity can be efficiently used in automotive power conversion systems and in other applications of the semiconductor power entity. The half bridge configuration is a reoccurring key topology element in power electronics conversion circuits.

In an exemplary implementation of the semiconductor power entity, the first power semiconductor is a vertical device including at least one first terminal opposing the first laminate upper main face and a second terminal opposing the first laminate lower main face; and the second power semiconductor is a vertical device including at least one first terminal opposing the second laminate upper main face and a second terminal opposing the second laminate lower main face.

This provides at least the advantage that the semiconductor power entity can provide high current density, high power dissipation and high reverse breakdown voltage.

In an alternative exemplary implementation of the semiconductor power entity, the first power semiconductor can be a lateral device and the second power semiconductor can be a lateral device.

In an exemplary implementation of the semiconductor power entity, the semiconductor power entity includes: at least one first via and at least one second via extending through the first laminate layer, the at least one first via forming an electrical connection between the at least one first terminal of the first power semiconductor and the first metal layer and the at least one second via forming an electrical connection between the second terminal of the first power semiconductor and the second metal layer; and at least one third via and at least one fourth via extending through the second laminate layer, the at least one third via forming an electrical connection between the at least one first terminal of the second power semiconductor and the third metal layer and the at least one fourth via forming an electrical connection between the second terminal of the second power semiconductor and the fourth metal layer.

Such a design provides at least the advantage that the shortest path between the two facing inner terminals of the power semiconductors can be used for electrical connection. This results in low parasitic impedance, high current capability of this buried connection due to large area. It can be even made larger than the die itself. Without this technique, such connections are only possible by arrangement of through-holes at the periphery outside the projected die area.

By such design both power semiconductors can be fully embedded in the respective laminate layers which results in excellent electrical performance.

In an alternative embodiment, these vias can be replaced by large area connections such that either the die front or the die back side can be in direct connection to the metal layers without any distance. Note that the large area connections can be made on one face of the chip per layer. With development and process modification large area connections can be on both sides, but in such a case there most likely would be one large area connection/via instead of multiple small vias.

These large area connections have at least the advantage that configurations are possible that allow further optimization of a) parasitic impedance by shortening the electrical path, or b) thermal path by enabling direct heat extraction without microvias at the outer surface of the entity.

In an exemplary implementation of the semiconductor power entity, the first power semiconductor has a first semiconductor upper main face and a first semiconductor lower main face opposing the first semiconductor upper main face; where the first semiconductor upper main face is coplanar arranged with the first laminate upper main face to form an electrical connection between the at least one first terminal of the first power semiconductor and the first metal layer at the first laminate upper main face; and where the second terminal of the first power semiconductor forms an electrical connection with the second metal layer at the first laminate lower main face by one or more microvias extending through the first laminate layer. Alternatively, the first semiconductor lower main face is coplanar arranged with the first laminate lower main face to form an electrical connection between the second terminal of the first power semiconductor and the second metal layer at the first laminate lower main face; and where the at least one first terminal of the first power semiconductor forms an electrical connection with the first metal layer at the first laminate upper main face by one or more microvias extending through the first laminate layer.

Such a design provides at least the advantage of large area chip connection on one side of the chip with the respective metal layer which provides improved thermal dissipation and improved electrical performance.

In an exemplary implementation of the semiconductor power entity, the second power semiconductor has a second semiconductor upper main face and a second semiconductor lower main face opposing the second semiconductor upper main face; where the second semiconductor upper main face is coplanar arranged with the second laminate upper main face to form an electrical connection between the at least one first terminal of the second power semiconductor and the third metal layer at the second laminate upper main face; and where the second terminal of the second power semiconductor forms an electrical connection with the fourth metal layer at the second laminate lower main face by one or more microvias extending through the second laminate layer. Alternatively, the second semiconductor lower main face is coplanar arranged with the second laminate lower main face to form an electrical connection between the second terminal of the second power semiconductor and the fourth metal layer at the second laminate lower main face; and where the at least one first terminal of the second power semiconductor forms an electrical connection with the third metal layer at the second laminate upper main face by one or more microvias extending through the second laminate layer.

Such a design provides at least the same advantage of large area chip connection on one side of the chip with the respective metal layer as described above. This large area chip connection results in improved thermal dissipation and improved electrical performance.

According to the sixth aspect, the embodiments relate to a method for producing a semiconductor power entity, the method including: providing a first laminate layer embedding a first power semiconductor, the first laminate layer having a first laminate upper main face and a first laminate lower main face opposing the first laminate upper main face; where a first metal layer is arranged at the first laminate upper main face of the first laminate layer and a second metal layer is arranged at the first laminate lower main face of the first laminate layer; providing a second laminate layer embedding a second power semiconductor, the second laminate layer having a second laminate upper main face and a second laminate lower main face opposing the second laminate upper main face; where a third metal layer is arranged at the second laminate upper main face of the second laminate layer and a fourth metal layer is arranged at the second laminate lower main face of the second laminate layer; applying a bonding metal at the second metal layer of the first laminate layer and/or the third metal layer of the second laminate layer, the bonding metal being placed between the first power semiconductor and the second power semiconductor and/or between respective electrical contact pairs in the first laminate layer and the second laminate layer, arranging an isolation layer between the second metal layer of the first laminate layer and the third metal layer of the second laminate layer; and laying-up and laminating the first laminate layer, the second laminate layer and the isolation layer to a semiconductor power entity, where the laminating transforms the bonding metal to a connection metal layer forming an electrical connection with the second metal layer and the third metal layer.

Such method or process provides at least the advantage to form the above-described vertical connections. The method or process provides at least the following advantageous characteristics: use of a standard PCB lamination process with respect to bond temperature, pressure, format; use of hybrid bonding to bond metal to metal and dielectric to dielectric in one step; several premanufactured layers can be connected to each other in one lamination step or in several sequential lamination steps; the bonding materials can be attached or applied to the surface of the laminate layers or placed between the laminate layers prior to bonding.

In an exemplary implementation of the method, the connection metal layer is formed simultaneously with the lamination of the first laminate layer, the second laminate layer and the isolation layer.

This provides at least the advantage that the fabrication method can be simplified due to performing two production steps simultaneously.

In an exemplary implementation of the method, the method includes: applying the bonding metal at the second metal layer of the first laminate layer; before the laying-up and laminating; and applying the isolation layer at the third metal layer of the second laminate layer before the laying-up and laminating, where the isolation layer is structured to form an opening for embedding the bonding metal.

This provides at least the advantage of flexibility in the sequence of the different production steps. It does not matter, for example, to which laminate layer the bonding metal or the isolation layer is applied to. They only need to be complementary.

In an exemplary implementation of the method, applying the bonding metal includes plating of metals, printing or dispending of pastes, placing of preforms; and where applying the isolation layer includes printing, coating, laminating or dispensing of dielectric material.

This provides at least the advantage of providing alternatives for application of the bonding metal and application of the isolation layer.

In an exemplary implementation of the method, the method includes: applying the isolation layer at the third metal layer of the second laminate layer before the laying-up and laminating, where the isolation layer is structured to form an opening for embedding the bonding metal; and placing the bonding metal into the opening of the isolation layer on the third metal layer.

This provides at least the advantage of flexibility in the sequence of the different production steps.

In an exemplary implementation of the method, the method includes: placing the isolation layer between the second metal layer of the first laminate layer and the third metal layer of the second laminate layer during the laying-up and laminating, where the isolation layer is non-structured.

This provides at least the advantage of flexibility in the sequence of the different production steps.

In an exemplary implementation of the method, the method includes: placing the isolation layer between the second metal layer of the first laminate layer and the third metal layer of the second laminate layer during the laying-up and laminating, where the isolation layer is structured to form an opening for embedding the bonding metal.

This provides at least the advantage of providing alternatives for placement of the isolation layer.

Following process steps of the above method are optional: drilling holes in the semiconductor power entity extending from the first metal layer to the fourth metal layer, where the holes are drilled laterally to the first and second power semiconductors; metal plating the holes to form metal plated through holes electrically connecting the first and optionally second, third metal layers with the fourth metal layer; and structuring the first metal layer and the fourth metal layer.

According to the seventh aspect, the embodiments relate to a computer program product including computer executable code or computer executable instructions that, when executed, causes at least one computer to execute the method according to the second aspect described above.

The computer program product may run on a controller or a processor for implementing the above method to produce the semiconductor power entity according to the first aspect described above.

According to the eighth aspect, the embodiments relate to a computer-readable medium, storing instructions that, when executed by a computer, cause the computer to execute the method according to the second aspect described above. Such a computer readable medium may be a non-transient readable storage medium, also called a non-transitory computer readable medium. The instructions stored on the non-transitory computer-readable medium may be executed by a controller or a processor.

### BRIEF DESCRIPTION OF THE DRAWINGS

Further embodiments will be described with respect to the following figures, in which:

FIG. 1 shows a schematic cross section of a semiconductor power entity according to an embodiment;

FIG. 2 shows a schematic cross section of a cooled semiconductor power module including a hybrid bond sheet 200 according to the embodiments;

FIG. 3a shows and example of a force-fitted non-positive metal connection by polymer shrink for a cooled semiconductor power module including a hybrid bond sheet according to a first embodiment;

FIG. 3b shows and example of a force-fitted non-positive metal connection by polymer shrink for a cooled semiconductor power module including a hybrid bond sheet according to a first embodiment;

FIG. 3c shows and example of a force-fitted non-positive metal connection by polymer shrink for a cooled semiconductor power module including a hybrid bond sheet according to a first embodiment;

FIG. 4a shows an example of a positive bonded metal connection formed by diffusion soldering with IMCs at the interface for a cooled semiconductor power module including a hybrid bond sheet according to a second embodiment;

FIG. 4b shows an example of a positive bonded metal connection formed by diffusion soldering with IMCs at the interface for a cooled semiconductor power module including a hybrid bond sheet according to a second embodiment;

FIG. 5a shows an example of a positive bonded metal connection formed by sintering for a cooled semiconductor power module including a hybrid bond sheet according to a third embodiment;

FIG. 5b shows an example of a positive bonded metal connection formed by sintering for a cooled semiconductor power module including a hybrid bond sheet according to a third embodiment;

FIG. 6a shows an example of a positive bonded metal/dielectric hybrid connection formed by glue infiltrated nanowires for a cooled semiconductor power module including a hybrid bond sheet according to a fourth embodiment;

FIG. 6b shows an example of a positive bonded metal/dielectric hybrid connection formed by glue infiltrated nanowires for a cooled semiconductor power module including a hybrid bond sheet according to a fourth embodiment;

FIG. 7a shows an example of a hybrid bond sheet with locally variable heat conductivity by variation of metal versus polymer ratio or by subdividing large metal islands into smaller patterns according to a fifth embodiment;

FIG. 7b shows an example of a hybrid bond sheet with locally variable heat conductivity by variation of metal versus polymer ratio or by subdividing large metal islands into smaller patterns according to a fifth embodiment;

FIG. 7c shows an example of a hybrid bond sheet with locally variable heat conductivity by variation of metal versus polymer ratio or by subdividing large metal islands into smaller patterns according to a fifth embodiment; and

FIG. 8 shows a schematic cross section of a cooled semiconductor power module 800 including a hybrid bond sheet where vertical structures are independent of surface pattern according to a sixth embodiment.

### DETAILED DESCRIPTION OF EMBODIMENTS

In the following detailed description, reference is made to the accompanying drawings, which form a part thereof, and in which is shown by way of illustration specific aspects in which the embodiments may be practiced. It is understood that other aspects may be utilized and structural or logical changes may be made without departing from the scope of the embodiments. The following detailed description, therefore, should not be interpreted as limiting.

It is understood that comments made in connection with a described method may also hold true for a corresponding device or system configured to perform the method and vice versa. For example, if a specific method step is described, a corresponding device may include a unit to perform the described method step, even if such unit is not explicitly described or illustrated in the figures. Further, it is understood that the features of the various exemplary aspects described herein may be combined with each other, unless specifically noted otherwise.

In this embodiments, diffusion soldering is described. The principle of diffusion soldering is applied to microelectronics since the 1960ies. It is also known as SLID, TLPB (transient liquid phase bonding), or isothermal solidification. It was since then applied to 3D-integration/chip-stacking and MEMS wafer level encapsulation. Diffusion soldering is an irreversible process, the connection does not remelt at the same temperature it is formed, but at a much higher temperature because all low-temperature melting solder is transformed into intermetallic compounds which have a higher melting temperature.

In the embodiments, sintering is described. Sintering is another low temperature metal joining technology that allows to make non-remeltable stable and reliable connections at a relatively low bond temperature. It is based on the high self-diffusion and surface diffusion property of some metals (silver and copper are most known and applied today), for example if the initial surface is very large. In some embodiments, a paste is printed and dried on a noble metal surface. The paste contains silver particles of different sizes and with a specific coating that prevents premature agglomeration and unwanted sintering. Under temperature and pressure, the dried paste densifies into a porous metal layer that forms a metallurgical bond with the compatible metal surfaces in contact. Another way to offer large sinterable metal surfaces is in form of metal filaments or wires that are grown on the contact surface, with diameters in the lower μm down to upper nm range and lengths of several tens of μm.

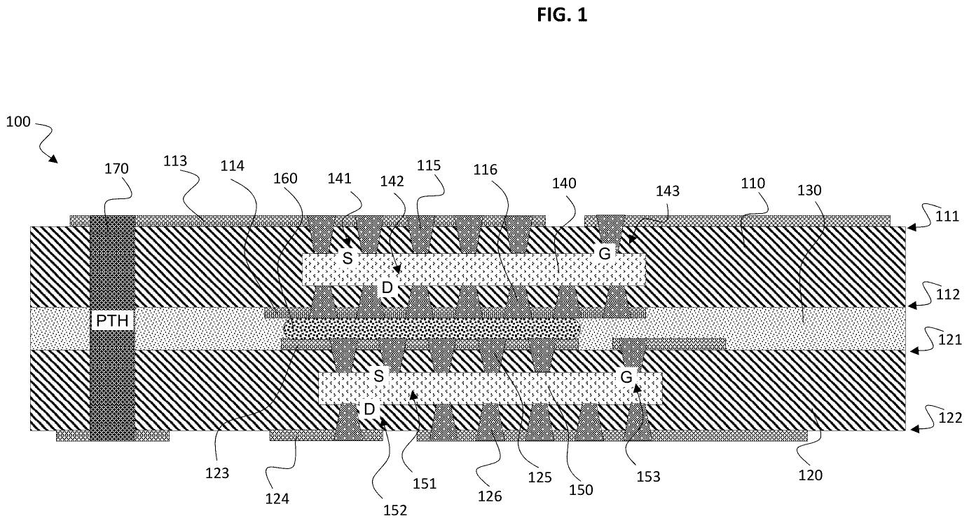

FIG. 1 shows a schematic cross section of a semiconductor power entity 100 according to a first embodiment.

The semiconductor power entity 100, also referred to as a semiconductor power product, includes a first laminate layer 110 having a first laminate upper main face 111 and a first laminate lower main face 112 opposing the first laminate upper main face 111; and a second laminate layer 120 having a second laminate upper main face 121 and a second laminate lower main face 122 opposing the second laminate upper main face 121.

The semiconductor power entity 100 includes an isolation layer 130 arranged between the first laminate layer 110 and the second laminate layer 120.

The semiconductor power entity 100 includes a first metal layer 113 arranged at the first laminate upper main face 111 of the first laminate layer 110 and a second metal layer 114 arranged at the first laminate lower main face 112 of the first laminate layer 110.

The semiconductor power entity 100 includes a third metal layer 123 arranged at the second laminate upper main face 121 of the second laminate layer 120 and a fourth metal layer 124 arranged at the second laminate lower main face 122 of the second laminate layer 120.

The semiconductor power entity 100 includes a connection metal layer 160 embedded in the isolation layer 130 between the first laminate layer 110 and the second laminate layer 120. The connection metal layer 160 is forming an electrical connection with the second metal layer 114 and the third metal layer 123.

The first, second, third and fourth metal layers 113, 114, 123, 124 can be redistribution or routing metal layers for redistributing or routing current paths.

As mentioned above, the semiconductor power entity can also be referred to as semiconductor power product. Such product can also be a module or a larger size product (PCB), for example, where the power components are embedded inside the PCB and the rest of the components on top. As described above, also part of the passives can be embedded inside the PCB.

The connection metal layer 160 can form a non-remelting electrical and mechanical connection.

Such a “non-remelting” connection is different from a normal solder connection such as formed during a conventional TC/NCP process (thermo-compression bonding with solder and pre-applied non-conductive polymer). A non-remelting connection is a connection which does not remelt in same temperatures at which the connection was formed.

The connection metal layer 160 can form one of a diffusion soldering connection or a sintering connection as described above in the section “detailed description of embodiments”.

The connection metal 160 can form a composed metal layer, for example. Such composed metal layer may include a compound from more than two metals, e.g., such as inter-metallic layer, or a connection of metal layers including one single metal, or a connection of a metal and a polymer or polymer mixture.

For such inter-metallic layer, the melting point of the inter metallic layer is higher than the lamination/process temperature where it was formed.

The connection metal layer may include more than 80% metal and less than 20% pores or polymers, for example.

The connection metal layer is designed for high current loads.

In one embodiment, the inter-metallic layer may have a minimum lateral size of greater than 1 mm in each dimension, but not smaller than about 0.1 mm.

The intermetallic layer may have a large cross-section, short length, and good conduction capabilities and, due to that, is suitable for high current loads.

In one embodiment, the inter-metallic layer may have a thickness of about 5 to 50 μm, but not thicker than about 0.2 mm (in case of a single layer structure).

As mentioned above, the laminate layers may embed or not embed power dies.

The first laminate layer 110 may embed a first power semiconductor 140 and/or the second laminate layer 120 may embed a second power semiconductor 150. In one example, only one of the laminate layers 110, 120 may be embedding a semiconductor component.

When defining a first power semiconductor and a second power semiconductor this does not exclude that more than one first power semiconductor can be embedded in the first laminate layer 110 and more than one second power semiconductor can be embedded in the second laminate layer 120.

The connection metal layer 160 may vertically connect the second metal layer 114 with the third metal layer 123 providing a vertical electrical connection for the first power semiconductor 140 and the second power semiconductor 150.

The connection metal layer 160 may form a direct electrical connection path between the first power semiconductor 140 and the second power semiconductor 150 without a detour via through-hole vias arranged laterally to the two power semiconductors 140, 150.

The second metal layer 114 and/or the third metal layer 123 may include at least one of copper, gold, silver, palladium, or nickel or a combination thereof. In case of a diffusion soldering connection, the connection metal layer 160 may include any of a suitable low temperature melting metal like for example the metals tin and indium in combination with any of the metals of the second metal layer 114 or the third metal layer 123 or an alloy thereof. In case of a sintering connection, the connection metal layer 160 may include a porous layer of silver or copper or other suitable sintering metal with optional polymer filling.

Note that such connection metal layer can include also the following combination: (tin OR indium OR (tin AND indium)) in combination with any of the metals of the second metal layer (114) or the third metal layer (123) or an alloy thereof.

The first power semiconductor 140 and the second power semiconductor 150 may be configured to form a half bridge configuration.

The first power semiconductor 140 can be a vertical device including at least one first terminal 141, 143 (e.g., source 141 and gate 143) opposing the first laminate upper main face 111 and a second terminal 142 (e.g., drain 142) opposing the first laminate lower main face 112.

The second power semiconductor 150 can be a vertical device including at least one first terminal 151, 153 (e.g., source 151 and gate 153) opposing the second laminate upper main face 121 and a second terminal 152 (e.g. drain 152) opposing the second laminate lower main face 122.

The semiconductor power entity 100 may include at least one first via 115 and at least one second via 116 extending through the first laminate layer 110. The at least one first via 115 may form an electrical connection between the at least one first terminal 141, 143 of the first power semiconductor 140 and the first metal layer 113. The at least one second via 116 may form an electrical connection between the second terminal 142 of the first power semiconductor 140 and the second metal layer 114.

The semiconductor power entity 100 may include at least one third via 125 and at least one fourth via 126 extending through the second laminate layer 120. The at least one third via 115 may form an electrical connection between the at least one first terminal 151, 153 of the second power semiconductor 150 and the third metal layer 123. The at least one fourth via 126 may form an electrical connection between the second terminal 152 of the second power semiconductor 150 and the fourth metal layer 124.

In an alternative embodiment, the vias 115, 116 can be replaced by large area connections such that the die front or back side can be in direct connection to the metal layers 113, 123 without any distance. Note that the large area connections can be made on one face of the chip per layer. With development and process modification large area connection can be on both sides (but in such a case there most likely would be one large area connection/via instead of multiple small vias).

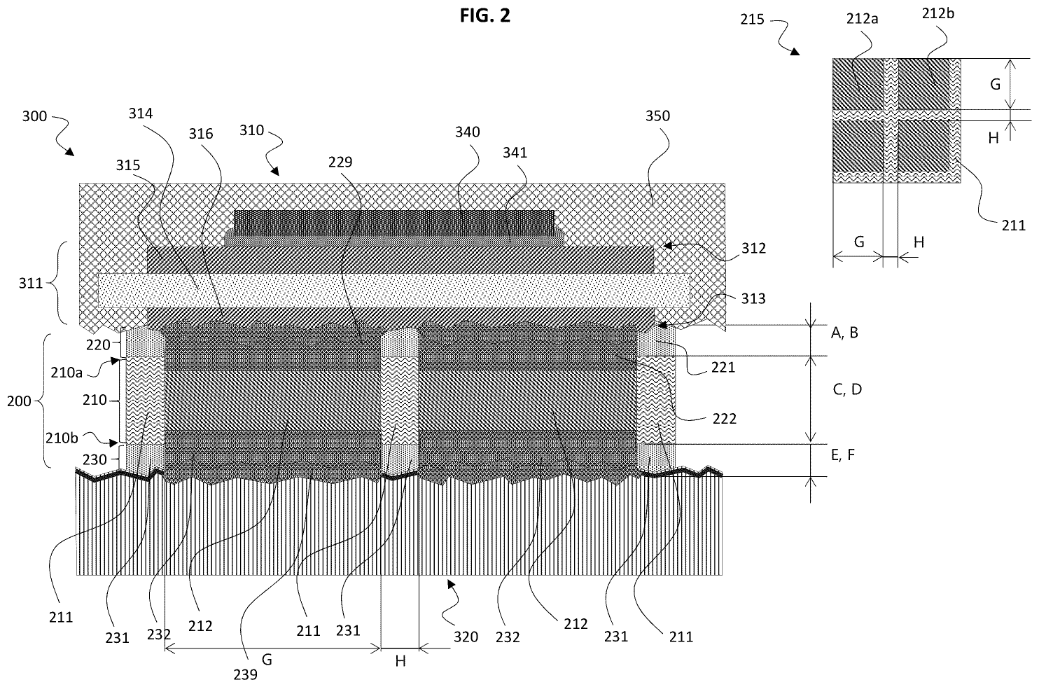

The connection metal layer 160 described above can alternatively be implemented by a hybrid bond sheet 200 as described below with respect to FIGS. 2 to 8.

FIG. 2 shows a schematic cross section of a cooled semiconductor power module 300 including a hybrid bond sheet 200 according to the embodiments.

The hybrid bond sheet 200 can be applied for mounting a semiconductor power module 310 to a heat sink 320 as shown in FIG. 2. Alternatively, the hybrid bond sheet 200 can be applied for mounting a first laminate layer 110 with or without a first power semiconductor 140 to a second laminate layer 120 with or without a second power semiconductor 150 as shown in FIG. 1.

The hybrid bond sheet 200 includes a thermally conductive core layer 210, a first bond layer 220 and a second bond layer 230.

The thermally conductive core layer 210 has an upper main face 210a and a lower main face 210b opposing the upper main face 210a.

The first bond layer 220 is formed at the upper main face 210a of the core layer 210 for bonding the hybrid bond sheet 200 to a semiconductor power module 310 as shown in FIG. 2.

The second bond layer 230 is formed at the lower main face 210b of the core layer 210 for bonding the hybrid bond sheet 200 to a heat sink 320 as shown in FIG. 2.

The core layer 210 is subdivided into a plurality of core metal sections 212 and core polymer sections 211 which are formed side-by-side between the upper main face 210a and the lower main face 210b. The subdivided core metal sections 212 are configured to enable a uniform heat transfer between the semiconductor power module 310 and the heat sink 320 and to reduce thermal stress at interfaces between the hybrid bond sheet 200 and the heat sink 320.

As already mentioned above, hybrid bond sheet means that bonding of the two joining members 310, 320 includes more than one (for example two) bonding mechanisms, an electrically conductive metallurgical bond, and a dielectric, electrically isolating bond. The two bond mechanisms act in laterally separated partial areas of the bond sheet 200, which is brought in between the two joining partners 310, 320.

A hybrid bond 200 sheet is thus a bond sheet made of different material layers such as metals and dielectrics.

As already mentioned above, hybrid bonding means the simultaneous bonding of metallic and dielectric surfaces to form void-free positive connections between metals and metals, dielectrics and dielectrics, and between metals and dielectrics. The term refers to wafer level bonding, chip-level bonding, panel level bonding, but also to discrete one-by-one power module to heatsink bonding.

The critical parameter here is thermal stress. When thermal stress is increasing, the power module 310 may disconnect or delaminate from the heatsink 320.

The interfaces between the hybrid bond sheet 200 and the heat sink 320 can be the interfaces of the second bond layer, e.g. interfaces of the metal sections 232 and the polymer sections 231 of the second bond layer.

The subdivided core polymer sections 211 can form a core polymer grid 215 that is subdividing the core metal sections 212 into core metal islands 212a, 212b as shown in the top right part of FIG. 2.

The core polymer grid 215 may include evenly shaped sections and/or unevenly shaped sections.

A size (G) of the core metal islands 212a, 212b can be greater than a size (H) of the core polymer grid 215 as can be seen from the core polymer grid 215 depicted on the top right side of FIG. 2.

The plurality of core metal sections 212 and core polymer sections 211 can be formed according to a heat dissipation pattern of the semiconductor power module 310.

This enables compensation of a non-uniform heat conduction between the semiconductor power module 310 and the heat sink 320 and also enables compensation of non-uniform temperature distribution of power semiconductor chip junction temperature.

A basic idea is to achieve a uniform junction temperature of all power dies, so that the switching behavior and lifetime consumption during operation is more uniform. Otherwise, the hottest device would shorten lifetime and worsen switching behavior of the overall module.

The core layer 210 may include at least one of the following areas: areas in which an area fraction of the core metal sections 212 is higher than an area fraction of the core polymer sections 211; areas in which an area fraction of the core polymer sections 211 is higher than an area fraction of the core metal sections 212; and areas in which an area fraction of the core metal sections 212 is equal to an area fraction of the core polymer sections 211.

The area fraction of the core metal sections specifies a merged area of all core metal sections versus an overall core layer interface area.

The area fraction of the core polymer sections specifies a merged area of all core polymer sections versus an overall core layer interface area.

The first bond layer 220 may be subdivided into a plurality of first bond metal sections 222 and first bond polymer sections 221 which are formed side-by-side on the upper main face 210a of the core layer 210.

Similarly, the second bond layer 230 may be subdivided into a plurality of second bond metal sections 232 and second bond polymer sections 231 which are formed side-by-side at the lower main face 210b of the core layer 210.

The first bond layer 220 may be configured to provide a simultaneous bonding by the following two mechanisms: metallurgical bonding of the first bond metal sections 222 to any metal; and glueing or encapsulating of the first bond polymer sections 221 to form an insulating bond to any surface.

Similarly, the second bond layer 230 may be configured to provide a simultaneous bonding by the following two mechanisms: metallurgical bonding of the second bond metal sections 232 to any metal; and glueing or encapsulating of the second bond polymer sections 231 to form an insulating bond to any surface.

A first bond interface 229 formed by the first bond layer 220 can be designed to be free of channels, voids, gaps or unfilled spaces as shown in FIG. 2.

Similarly, a second bond interface 239 formed by the second bond layer 230 can be designed to be free of channels, voids, gaps or unfilled spaces.

A material of the plurality of first bond metal sections 222 may be different or the same as a material of the core metal sections 212.

Similarly, a material of the plurality of second bond metal sections 232 may be different or the same as a material of the core metal sections 212.

Each of the materials specified above, e.g. material of the bond metal sections 222, 232 and material of the core metal sections 212 can be a metal or metal paste or semi metal (like Carbon) with high thermal conductivity, that can also be electrically conductive and is not required to be electrically isolating but is capable of forming a bond to the heatsink 320 or to the power module 310.

In one example, the metallurgical bonding is by soldering and the core metal section has a plated solder finish, as does the first/second bond metal sections. Here, both materials can be the same.

The first bond metal sections 222 of the first bond layer 220 can be aligned with the core metal sections 212 of the core layer 210.

The first bond polymer sections 221 of the first bond layer 220 can be aligned with the core polymer sections 211 of the core layer 210.

The second bond metal sections 232 of the second bond layer 230 can be aligned with the core metal sections 212 of the core layer 210.

The second bond polymer sections 231 of the second bond layer 230 can be aligned with the core polymer sections 211 of the core layer 210.

Or in other words, the core metal sections 212 may be following the pattern of the bond metal sections; and the core polymer sections 211 may be following the pattern of the bond polymer sections.

The subdivision of the first bond metal sections 222 and the first bond polymer sections 221 may form a different pattern than the subdivision of the core metal sections 212 and the core polymer sections 211.

Similarly, the subdivision of the second bond metal sections 232 and the second bond polymer sections 231 may form a different pattern than the subdivision of the core metal sections 212 and the core polymer sections 211.

The above features may be of advantage for the case where the core metal sections are merged into one continuous metal layer for heat conduction and spreading, but with higher risk of increased thermal stress due to large area accumulation of thermal expansion.

The subdivided first bond polymer sections 221 can form a first polymer grid and the subdivided core polymer sections 211 can form a second polymer grid. A width of the first polymer grid can be different from a width of the second polymer grid.

The first polymer grid may be subdividing the first bond metal sections 221 into metal islands. The second polymer grid may be subdividing the core metal sections 212 into metal islands. The metal islands formed by the second polymer grid can be larger than the metal islands formed by the first polymer grid.

Or in other words, the subdivided metal sections can be separated by polymer sections; and the subdivided core metal sections can be separated by core polymer sections.

The subdivided core metal sections 212 can form a core metal grid 215 that is subdividing the core polymer sections 211 into core polymer islands.

The metal grid formed by the subdivided core metal sections 212 may include a leadframe.

As mentioned above, the hybrid bond sheet 200 can be applied for mounting a semiconductor power module 310 to a heat sink 320. The whole device corresponds to a cooled semiconductor power module 300 as shown in FIG. 2.

Such cooled semiconductor power module 300 includes the semiconductor power module 310 and the hybrid bond sheet 200 and optionally the heat sink 320.

The semiconductor power module 310 may include: a thermally conductive substrate 311 having a substrate upper main face 312 and a substrate lower main face 313 opposing the substrate upper main face 312; a semiconductor chip 340 attached to the substrate upper main face 312; and a mold compound 350 at least partially encapsulating the semiconductor chip 340.

The hybrid bond sheet 200 is configured for bonding the semiconductor power module 310 to the heat sink 320 as follows:

The first bond layer 220 of the hybrid bond sheet 200 is attached to the substrate lower main face 313 forming a fully polymer encapsulated electrically and thermally conductive connection. The second bond layer 230 of the hybrid bond sheet 200 can be attached to the heat sink 320 forming another fully polymer encapsulated electrically and thermally conductive connection.

The cooled semiconductor power module 300 may include the heat sink 320 which may be attached to the semiconductor power module 310. Interfaces formed by the fully polymer encapsulated electrically and thermally conductive connection of the first bond layer 220 and/or the second bond layer 230 may form a non-remelting electrical and mechanical connection.

Interfaces formed by the fully polymer encapsulated electrically and thermally conductive connection of the first bond layer 220 and/or the second bond layer 230 may form one of a diffusion soldering connection, a sintering connection, a force-fitted metal connection or a nano-wire connection.

For the force-fitted metal connection, a contact force between the metal sections of the hybrid bond sheet 200 and respective metal sections of the substrate 311 and/or heat sink 320 may be initiated by the polymer sections which have a higher coefficient of thermal expansion than the metal sections.

That means, after the bonding a shrinking of the polymer sections is stronger than a shrinking of the metal sections which results in pressing the metal sections of hybrid bond sheet 200, substrate 311 and heat sink 320 against each other.

The embodiments also present a method for manufacturing such a hybrid bond sheet 200 for mounting a semiconductor power module 310 to a heat sink 320. The method includes the following:
forming a thermally conductive core layer 210 having an upper main face 210a and a lower main face 210b opposing the upper main face 210a;
forming a first bond layer 220 at the upper main face 210a of the core layer 210 for bonding the hybrid bond sheet 200 to a semiconductor power module 310; and
forming a second bond layer 230 at the lower main face 210b of the core layer 210 for bonding the hybrid bond sheet 200 to a heat sink 320; where the core layer 210 is subdivided into a plurality of core metal sections 212 and core polymer sections 211 which are formed side-by-side between the upper main face 210a and the lower main face 210b, the subdivided core metal sections 212 being configured to enable a uniform heat transfer between the semiconductor power module 310 and the heat sink 320 and to reduce thermal stress at interfaces between the hybrid bond sheet 200 and the heat sink 320.

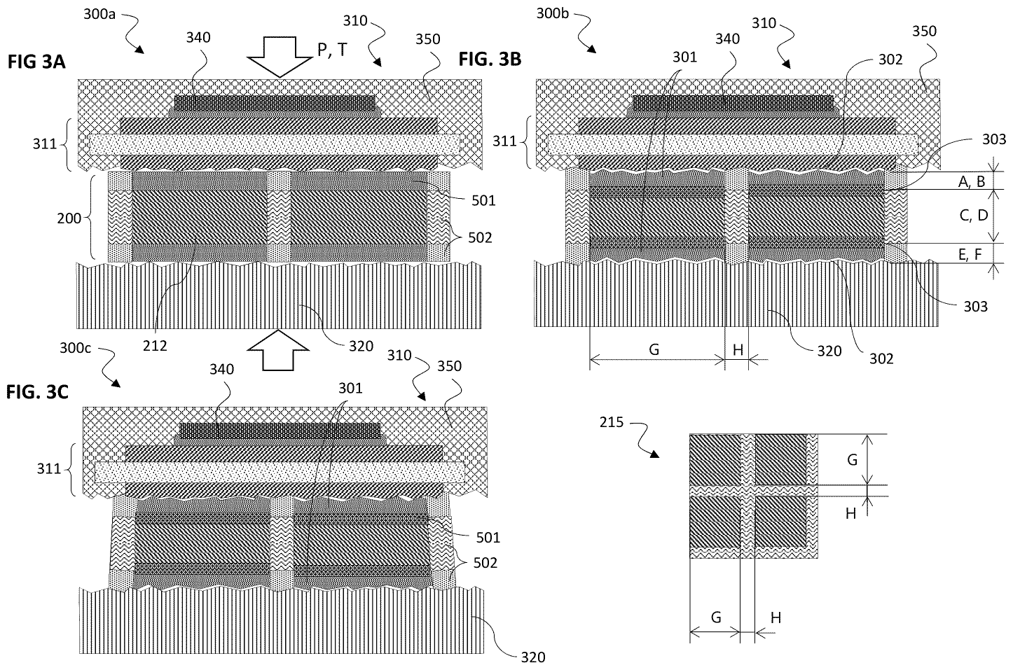

The embodiments also present a method for manufacturing such a cooled semiconductor power entity 300 as shown in FIG. 2 and in the following FIGS. 3 to 8. The method includes the following:
providing a semiconductor power module 310;
providing a heat sink 320;
placing a hybrid bond sheet 200 as described above between the semiconductor power module 310 and the heat sink 320;
thermally pressing the semiconductor power module 310 and the heat sink 320 against each other to activate the first bond layer 220 and the second bond layer 230 of the hybrid bond sheet 200 and to form bond connections between the semiconductor power module 310 and the heat sink 320.

In the following, seven embodiments of the hybrid bond sheet 200 are presented, where Embodiment 6 is not shown in the Figures.

Embodiments 1 to 4 as shown in FIGS. 3a to 6b represent variations of bond materials and metal bonding technology, equivalent compound thermal conductivity estimated by a lumped calculation model.

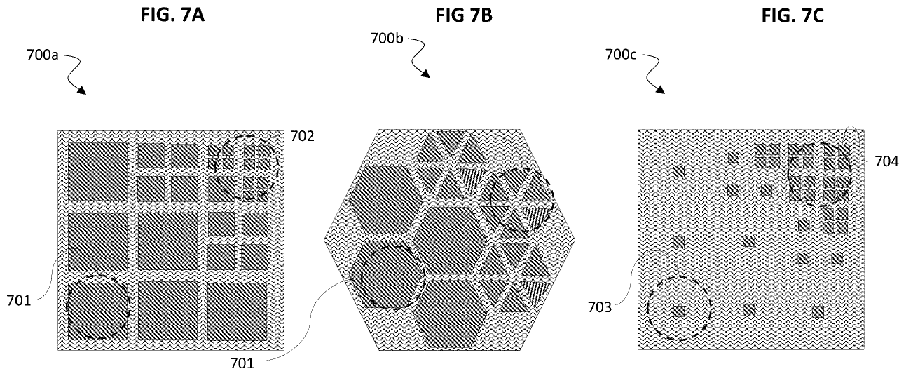

Embodiment 5 shown in FIGS. 7a, 7b, and 7c represents local variation of pattern.

Embodiment 6 represents an inverse pattern, e.g. polymer surrounded by a metal grid (not shown in the Figures).

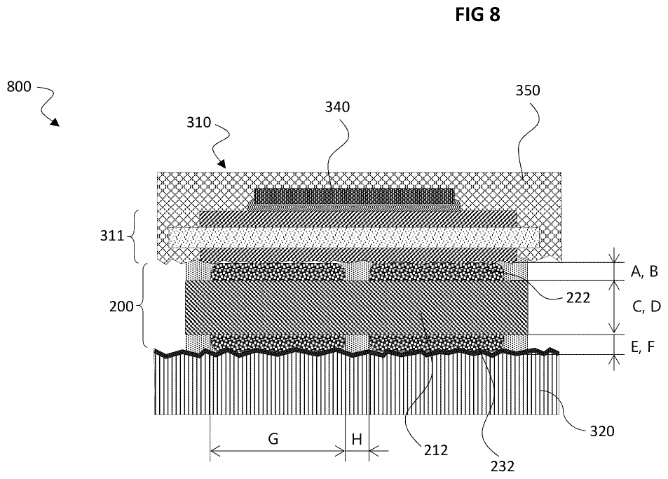

Embodiment 7 as shown in FIG. 8 represents a vertical structure being independent of the surface pattern.

FIGS. 3a, 3b and 3c show examples of a force-fitted non-positive metal connection by polymer shrink for a cooled semiconductor power module 300a, 300b, 300c including a hybrid bond sheet 200 according to a first embodiment.

The cooled semiconductor power modules 300a, 300b, 300c may be designed as described above with respect to FIG. 2 for the cooled semiconductor power module 300.

FIG. 3a shows the cooled semiconductor power module 300a prior to bonding. Bonding is depicted by the arrows illustrating the application of pressure (P) and temperature (T) to press the two joining members 310, 320 against the hybrid bond sheet 200.

FIG. 3b shows the cooled semiconductor power module 300b after the bonding and FIG. 3c shows the cooled semiconductor power module 300c under load.

In this first embodiment, shown in FIGS. 3a, 3b, 3c, the metal connection can be based on solder 501 that melts during joining, but does not require to wet the counter surface of the heatsink 320 or the cooling interface of the power module 310. The solder only needs to get in contact with the counter surfaces and adapt to their shape/surface morphology. It does not necessarily need to form a metallurgical connection by formation of intermetallic phases (IMCs). The polymer sections are depicted by 502.

For this first embodiment, the following design of the core polymer grid 215 is applied (see Table 1):

TABLE 1
design of the core polymer grid 215 for the first embodiment

| Description | | Typical | | Range | Material (e.g.) | |
|---|---|---|---|---|---|---|
| A | Upper metal bond | 50 | um | 20 μm . . . 100 μm | In, 81.8 | W/(m*K) |
| | layer | | | | | |
| B | Upper polymer bond | =A | | =A | 0.7 | W/(m*K) |
| | layer | | | | | |
| C | Carrier metal layer | 80 | um | 30 um . . . 200 um | Cu, 384 | W/(m*K) |
| D | Carrier polymer layer | =C | | =C | 0.7 | W/(m*K) |
| E | Lower metal bond | 50 | um | 20 μm . . . 100 μm | In, 81.8 | W/m*K) |
| | layer | | | | | |
| F | Lower polymer bond | =E | | =E | 0.7 | W/(m*K) |
| | layer | | | | | |

| | | | | | |
|---|---|---|---|---|---|
| G | Metal island size | 1.0 | mm | 0.1 mm . . . 5.0 mm | =C |
| H | Polymer grid size | 0.2 | mm | 0.1 mm . . . 5.0 mm | =D |

This first embodiment is based on the idea that the thermal connection does not entirely rely on a metallurgical connection, because after bonding, during cool-down, the dielectric shrinks stronger than the metal. This creates a pulling force that presses the metal surfaces against each other and maintains a thermal contact during operation temperatures below T_G of the polymer.

The obtained thermal connection can be sufficient for many applications. It increases the range of possible applications because it does not require activated surfaces prior to bonding. It does not require matched and metallurgically compatible solder/contact metallization couples to form stable IMCs. In addition, it has a potentially high tolerance against mismatched CTEs because it has a degree of compliance to lateral in-plane movements due to the polymer matrix the metal contacts are embedded in.

A diffusion barrier layer such as for example Ni can be placed in between the vertical Cu bar/Cu islands 212 and the solder 501. This prevents solder consumption and conversion into intermetallic compounds (IMC) during operating life. Without a barrier layer, after some operation time, the thermal interface can be dominated by brittle IMC, which does not have sufficient plasticity to fulfil the required thermal gap filling function.

This first embodiment can be reworkable or repairable because no metallurgic connection is present, and the module can be non-destructively detached. The glued surfaces need to be cleaned from polymer residues prior to re-assembly.

Some key points of this first embodiment are: 1) surface gap filling by solder softening or melting during joining; 2) protected non-positive metal to metal connection embedded/encapsulated in polymer matrix; 3) pull force created during cool-down after bonding by polymer versus metal CTE ratio >1; 4) high versatility, but relatively low thermal performance due to non-positive metal connection; and 5) can be reworked/repaired.

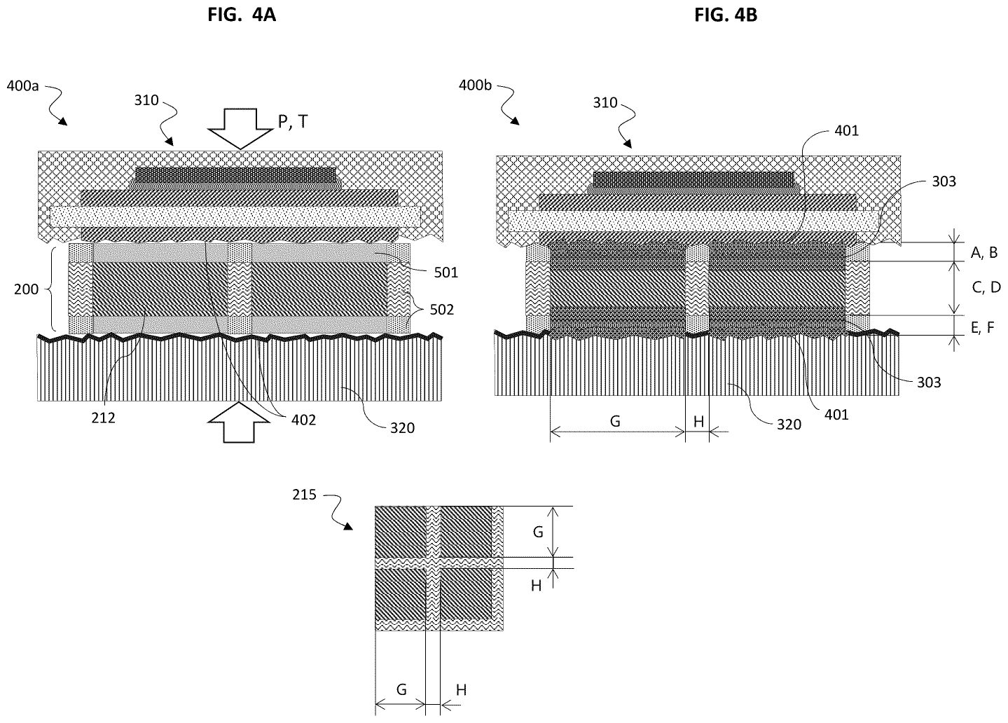

FIGS. 4a and 4b show examples of a positive bonded metal connection formed by diffusion soldering with IMCs at the interface for a cooled semiconductor power module 400a, 400b including a hybrid bond sheet 200 according to a second embodiment.

The cooled semiconductor power modules 400a, 400b may be designed as described above with respect to FIG. 2 for the cooled semiconductor power module 300.

FIG. 4a shows the cooled semiconductor power module 400a prior to bonding. Bonding is depicted by the arrows illustrating the application of pressure (P) and temperature (T) to press the two joining members 310, 320 against the hybrid bond sheet 200.

FIG. 4b shows the cooled semiconductor power module 400b after the bonding.

For embodiment 2, as shown in FIG. 4a, 4b, an equivalent through plane thermal conductivity of 120 W/(m*K) and an in-plane thermal conductivity of 20 W/(m*K) was estimated by a lumped calculation model as depicted in Table 3 (assumed perfect bonding, neglect contact thermal resistance).

For this second embodiment, the following design of the core polymer grid 215 is applied (see Table 2):

TABLE 2
design of the core polymer grid 215 for the second embodiment

| Description | | Typical | | Range | Material (e.g.) | |
|---|---|---|---|---|---|---|
| A | Upper metal bond | 50 | um | 20 μm . . . 100 μm | In, 81.8 | W/(m*K) |
| | layer | | | | | |
| B | Upper polymer bond | =A | | =A | 0.7 | W/(m*K) |
| | layer | | | | | |
| C | Carrier metal layer | 80 | um | 30 um . . . 200 um | Cu, 384 | W/(m*K) |
| D | Carrier polymer layer | =C | | =C | 0.7 | W/(m*K) |
| E | Lower metal bond | 50 | um | 20 μm . . . 100 μm | In, 81.8 | W/m*K) |
| | layer | | | | | |
| F | Lower polymer bond | =E | | =E | 0.7 | W/(m*K) |
| | layer | | | | | |

| | | | | | |
|---|---|---|---|---|---|
| G | Metal island size | 1.0 | mm | 0.1 mm . . . 5.0 mm | =C |
| H | Polymer grid size | 0.2 | mm | 0.1 mm . . . 5.0 mm | =D |

TABLE 3
estimated thermal conductivity based on lumped model

| Equivalent thermal conductivity | |
|---|---|
| of hybrid bond sheet | W/(m*K) |
| Z-direction | 120 |
| X, Y-direction | 20 |

Note:
assume perfect bonding, neglect contact thermal resistance

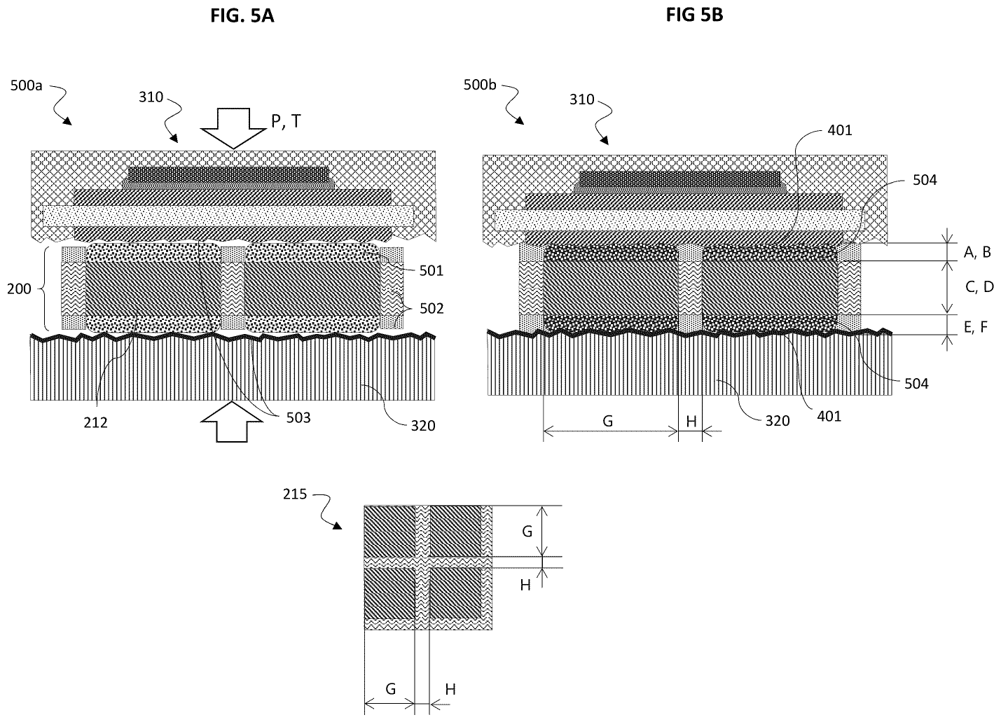

FIGS. 5a and 5b show examples of a positive bonded metal connection formed by sintering for a cooled semiconductor power module including a hybrid bond sheet 200 according to a third embodiment.

The cooled semiconductor power modules 500a, 500b may be designed as described above with respect to FIG. 2 for the cooled semiconductor power module 300.

FIG. 5a shows the cooled semiconductor power module 500a prior to bonding. Bonding is depicted by the arrows illustrating the application of pressure (P) and temperature (T) to press the two joining members 310, 320 against the hybrid bond sheet 200.

FIG. 5b shows the cooled semiconductor power module 500b after the bonding.

For embodiment 3 (see FIG. 5a, 5b) an equivalent through plane thermal conductivity of 190 W/(m*K) and an in-plane thermal conductivity of 38 W/(m*K) was estimated by a lumped calculation model (as shown in Table 5), assuming perfect bonding, neglecting contact thermal resistance.

For this third embodiment, the following design of the core polymer grid 215 is applied (see Table 4):

TABLE 4
design of the core polymer grid 215 for the third embodiment

| Description | | Typical | | Range | Material (e.g.) | |
|---|---|---|---|---|---|---|
| A | Upper metal bond | 20 | um | 5 μm . . . 100 μm | Ag (80%), ca. 200 | |
| | layer | | | | W/(m*K) | |
| B | Upper polymer bond | =A | | =A | 0.7 | W/(m*K) |
| | layer | | | | | |
| C | Carrier metal layer | 80 | um | 30 um . . . 200 um | Cu, 384 | W/(m*K) |
| D | Carrier polymer layer | =C | | =C | 0.7 | W/(m*K) |
| E | Lower metal bond | 20 | um | 5 μm . . . 100 μm | Ag (80%), ca. 200 | |
| | layer | | | | W/(m*K) | |
| F | Lower polymer bond | =E | | =E | 0.7 | W/(m*K) |
| | layer | | | | | |

| | | | | | |
|---|---|---|---|---|---|
| G | Metal island size | 1.0 | mm | 0.1 mm . . . 5.0 mm | =C |
| H | Polymer grid size | 0.2 | mm | 0.1 mm . . . 5.0 mm | =D |

TABLE 5
estimated thermal conductivity based on lumped model

| Equivalent thermal conductivity | |
|---|---|
| of hybrid bond sheet | W/(m*K) |
| Z-direction | 190 |
| X, Y-direction | 38 |

Note:
assume perfect bonding, neglect contact thermal resistance

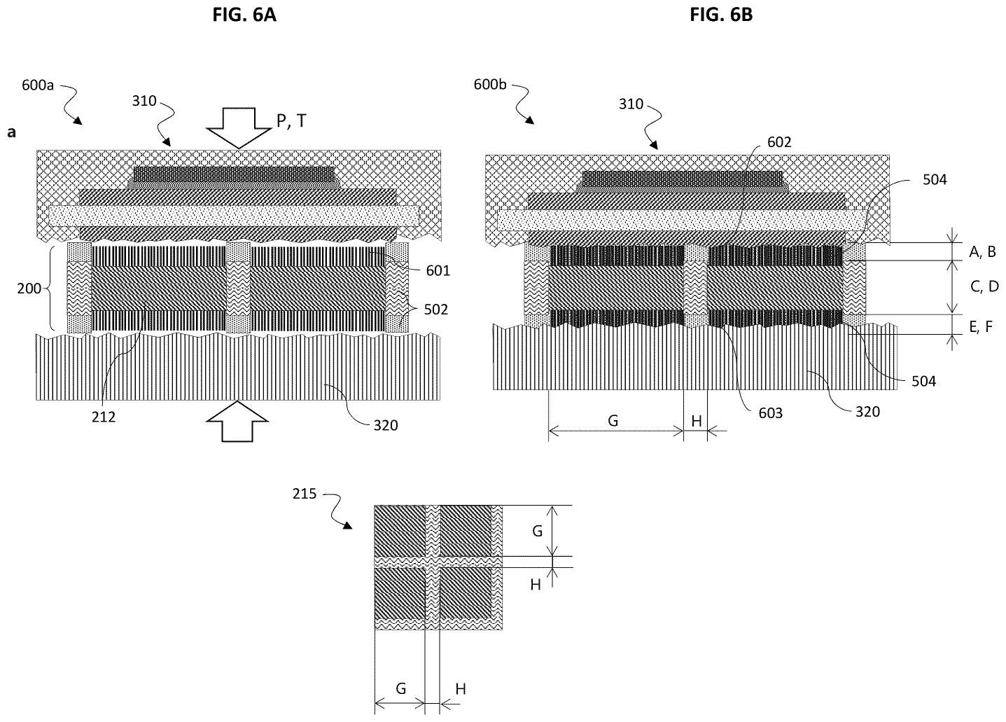

FIGS. 6a and 6b show examples of a positive bonded metal/dielectric hybrid connection formed by glue infiltrated nanowires for a cooled semiconductor power module including a hybrid bond sheet 200 according to a fourth embodiment.

The cooled semiconductor power modules 600a, 600b may be designed as described above with respect to FIG. 2 for the cooled semiconductor power module 300.

FIG. 6a shows the cooled semiconductor power module 600a prior to bonding. Bonding is depicted by the arrows illustrating the application of pressure (P) and temperature (T) to press the two joining members 310, 320 against the hybrid bond sheet 200.

FIG. 6b shows the cooled semiconductor power module 600b after the bonding.

For this fourth embodiment (FIGS. 6a, 6b) an equivalent through plane thermal conductivity of 210 W/(m*K) and an in-plane thermal conductivity of 40 W/(m*K) was estimated by a lumped calculation model as shown in Table 7 (assumed perfect bonding, neglect contact thermal resistance).

For this fourth embodiment, the following design of the core polymer grid 215 is applied (see Table 6):

TABLE 6
design of the core polymer grid 215 for the fourth embodiment

| Description | | Typical | | Range | Material (e.g.) | |
|---|---|---|---|---|---|---|
| A | Upper metal bond | 10 | um | 5 μm . . . 20 μm | Cu (80%), ca. 275 | |
| | layer | | | | W/(m*K) | |
| B | Upper polymer bond | =A | | =A | 0.7 | W/(m*K) |
| | layer | | | | | |
| C | Carrier metal layer | 80 | um | 30 um . . . 200 um | Cu, 384 | W/(m*K) |
| D | Carrier polymer layer | =C | | =C | 0.7 | W/(m*K) |
| E | Lower metal bond | 10 | um | 5 μm . . . 20 μm | Cu (80%), ca. 275 | |
| | layer | | | | W/(m*K) | |
| F | Lower polymer bond | =E | | =E | 0.7 | W/(m*K) |
| | layer | | | | | |

| | | | | | |
|---|---|---|---|---|---|
| G | Metal island size | 1.0 | mm | 0.1 mm . . . 5.0 mm | =C |
| H | Polymer grid size | 0.2 | mm | 0.1 mm . . . 5.0 mm | =D |

TABLE 7
estimated thermal conductivity based on lumped model

| Equivalent thermal conductivity | |
|---|---|
| of hybrid bond sheet | W/(m*K) |
| Z-direction | 210 |
| X, Y-direction | 40 |

Note:
assume perfect bonding, neglect contact thermal resistance

FIGS. 7a, 7b, and 7c show examples of a module footprint area 700a, 700b, 700c with locally variable heat conductivity by variation of metal versus polymer ratio or by subdividing large metal islands into smaller patterns according to a fifth embodiment.

The module may correspond to the cooled semiconductor power module 300 as described above with respect to FIGS. 2 to 6.

In the FIGS. 7a, 7b, and 7c, different area of heat conductivity are illustrated: an area with high in-plane heat conductivity (heat spreading) 701 is shown in FIGS. 7a and 7b. An area with low in-plane and high through-plane heat conductivity 702 is shown in FIG. 7a. An area with low through-plane heat conductivity 703 is shown in FIG. 7c. An area with high through-plane heat conductivity 704 is shown in FIG. 7c.

In this fifth Embodiment, the metal islands and vertical metallic through-connection areas can have a pattern that varies across the module footprint area (see FIGS. 7a, 7b and 7c). The footprint area of the module can have 1) areas with many small metal islands with an AR<1 (thickness to diameter ratio) which have a more directional heat conduction characteristics and an overall lower compound thermal conductivity. Alternative or additionally, the footprint area of the module can have 2) areas with few large metal islands with an AR >>1 which have a more isotropic heat conduction characteristics and an overall higher compound thermal conductivity, closer to the bulk metal thermal conductivity.

The areas 701, 702, 703, 704 with different thermal properties can be used to direct the heat flow and achieve a more uniform temperature distribution of the chip temperatures. The compensation pattern in the thermal management sheet can be used to achieve a narrow junction temperature distribution of the semiconductors in operation. This way, the overall performance of the power module can be increased, because the maximum allowed current can be defined by the chip with the highest junction temperature. In a narrower temperature distribution, the maximum allowed current can be higher.

The locally variable heat conductivity can compensate chip temperature non-uniformity within the module. This can increase the performance of the power module.

Another benefit of the more uniform junction temperature distribution is that as with the maximum allowed current, also the lifetime of the module can increase, because its weakest element will be closer to the average.

In a sixth embodiment (not shown in the Figures) an arrangement is provided where the surface pattern and the vertical connection structure of the thermal management sheet is reversed: The surface structure and vertical structure has polymer islands that are surrounded by a metal matrix/grid.

In an exemplary implementation of this embodiment, the metal grid can include a leadframe that has polymer filled half-etch recesses on the top and bottom surfaces in order to separate the large metal grid area into smaller L-shaped partitions. This can help to facilitate wetting during diffusion soldering. It can also be used to preserve the possibility of local variation of thermal conductivity for this embodiment.

FIG. 8 shows a schematic cross section of a cooled semiconductor power module 800 including a hybrid bond sheet 200 where vertical structures are independent of surface pattern according to a seventh embodiment.

The cooled semiconductor power module 800 may be designed as described above with respect to FIG. 2 for the cooled semiconductor power module 300.

In this seventh embodiment the bond layers on top and bottom of the hybrid bond sheet 200 are independent from the through-sheet column array. For example, the column islands can be larger than the bond layer islands, or even be connected together, as shown in FIG. 8.

While a particular feature or aspect of the embodiments may have been described with respect to only one of several implementations, such feature or aspect may be combined with one or more other features or aspects of the other implementations as may be desired and advantageous for any given or particular application. Furthermore, to the extent that the terms “include”, “have”, “with”, or other variants thereof are used, such terms are intended to be inclusive in a manner similar to the term “comprise”. Also, the terms “exemplary”, “for example” and “e.g.” are merely meant as an example, rather than the best or optimal. The terms “coupled” and “connected”, along with derivatives may have been used. It should be understood that these terms may have been used to indicate that two elements cooperate or interact with each other regardless whether they are in direct physical or electrical contact, or they are not in direct contact with each other.

Although specific aspects have been illustrated and described herein, it will be appreciated by those of ordinary skill in the art that a variety of alternate and/or equivalent implementations may be substituted for the specific aspects shown and described without departing from the scope of the embodiments. The embodiments are intended to cover any adaptations or variations of the specific aspects discussed herein.

Many alternatives, modifications, and variations will be apparent to those skilled in the art in light of the above teachings. Of course, those skilled in the art readily recognize that there are numerous applications of the embodiments beyond those described herein. While described with reference to one or more particular embodiments, those skilled in the art recognize that many changes may be made thereto without departing from the scope of the embodiments. It is therefore to be understood that within the scope of the embodiments and their equivalents, alternatives may be practiced otherwise than as specifically described herein.

1. A hybrid bond sheet configured to mount a semiconductor power module to a heat sink, the hybrid bond sheet comprising:
a thermally conductive core layer having an upper main face and a lower main face opposing the upper main face;
a first bond layer formed at the upper main face of the core layer and configured to bond the hybrid bond sheet to a semiconductor power module; and
a second bond layer formed at the lower main face of the core layer and configured to bond bonding the hybrid bond sheet to a heat sink, wherein the core layer is subdivided into a plurality of core metal sections and core polymer sections which are formed side-by-side between the upper main face and the lower main face, and the plurality of core metal sections is configured to enable a uniform heat transfer between the semiconductor power module and the heat sink and to reduce thermal stress at interfaces between the hybrid bond sheet and the heat sink.

2. The hybrid bond sheet of claim 1, wherein the plurality of core polymer sections is further configured to form a core polymer grid that is subdividing the core metal sections into core metal islands.

3. The hybrid bond sheet of claim 2, wherein the core polymer grid comprises evenly shaped sections.

4. The hybrid bond sheet of claim 2, wherein a size of the core metal islands is greater than a size of the core polymer grid.

5. The hybrid bond sheet of claim 1, wherein the plurality of core metal sections and the core polymer sections are formed according to a heat dissipation pattern of the semiconductor power module.

6. The hybrid bond sheet of claim 1, wherein the core layer comprises at least one of the following areas:
areas in which an area fraction of the core metal sections is higher than an area fraction of the core polymer sections.

7. The hybrid bond sheet of claim 1, wherein the first bond layer is subdivided into a plurality of first bond metal sections and first bond polymer sections which are formed side-by-side on the upper main face of the core layer; and
the second bond layer is subdivided into a plurality of second bond metal sections and second bond polymer sections which are formed side-by-side at the lower main face of the core layer.

8. The hybrid bond sheet of claim 7, wherein the first bond layer is configured to provide a simultaneous bonding by the following two mechanisms:
metallurgical bonding of the first bond metal sections to any metal; and
glueing or encapsulating of the first bond polymer sections to form an insulating bond to any surface; and
the second bond layer is configured to provide a simultaneous bonding by the following two mechanisms:
metallurgical bonding of the second bond metal sections to any metal; and
glueing or encapsulating of the second bond polymer sections to form an insulating bond to any surface.

9. The hybrid bond sheet of claim 7, wherein a first bond interface formed by the first bond layer is configured to be free of channels, voids, gaps or unfilled spaces; and a second bond interface formed by the second bond layer is configured to be free of channels, voids, gaps or unfilled spaces.

10. The hybrid bond sheet of claim 7, wherein a material of the plurality of first bond metal sections is different from a material of the core metal sections and a material of the plurality of second bond metal sections is different from as a material of the core metal sections.

11. The hybrid bond sheet of claim 7,
wherein the first bond metal sections of the first bond layer are aligned with the core metal sections of the core layer;
the first bond polymer sections of the first bond layer are aligned with the core polymer sections of the core layer;
the second bond metal sections of the second bond layer are aligned with the core metal sections of the core layer; and
the second bond polymer sections of the second bond layer are aligned with the core polymer sections of the core layer.

12. The hybrid bond sheet (200) of claim 7, wherein the subdivision of the first bond metal sections and the first bond polymer sections forms a different pattern than the subdivision of the core metal sections and the core polymer sections, and wherein the subdivision of the second bond metal sections and the second bond polymer sections forms a different pattern than the subdivision of the core metal sections and the core polymer sections.

13. The hybrid bond sheet of claim 7, wherein the subdivided first bond polymer sections form a first polymer grid, the subdivided core polymer sections form a second polymer grid, and a width of the first polymer grid is different from a width of the second polymer grid.

14. The hybrid bond sheet of claim 13, wherein the first polymer grid is subdividing the first bond metal sections into metal islands, the second polymer grid is subdividing the core metal sections into metal islands, and the metal islands formed by the second polymer grid are larger than the metal islands formed by the first polymer grid.

15. The hybrid bond sheet of claim 1, wherein the plurality of core metal sections forms a core metal grid that is subdividing the core polymer sections into core polymer islands.

16. The hybrid bond sheet (200) of claim 15, wherein the metal grid formed by the plurality of core metal sections comprises a leadframe.

17. A cooled semiconductor power module, comprising:
a semiconductor power module comprising:
a thermally conductive substrate having a substrate upper main face and a substrate lower main face opposing the substrate upper main face;
a semiconductor chip attached to the substrate upper main face;
a mold compound at least partially encapsulating the semiconductor chip; and
a hybrid bond sheet configured to bond the semiconductor power module to a heat sink; wherein the first bond layer of the hybrid bond sheet is attached to the substrate lower main face forming a first fully polymer encapsulated electrically and thermally conductive connection, and the second bond layer of the hybrid bond sheet is attached to the heat sink forming a second fully polymer encapsulated electrically and thermally conductive connection.

18. The cooled semiconductor power module of claim 17, wherein the heat sink is attached to the semiconductor power module, and interfaces formed by the fully polymer encapsulated electrically and thermally conductive connection of the first bond layer and the second bond layer form a non-remelting electrical and mechanical connection.

19. The cooled semiconductor power module of claim 17, wherein interfaces formed by the fully polymer encapsulated electrically and thermally conductive connection of the first bond layer and/or the second bond layer form one of a diffusion soldering connection, a sintering connection, a force-fitted metal connection, or a nano-wire connection.

20. A method for manufacturing a hybrid bond sheet for mounting a semiconductor power module to a heat sink, the method comprising:
forming a thermally conductive core layer having an upper main face and a lower main face opposing the upper main face;
forming a first bond layer at the upper main face of the core layer for bonding the hybrid bond sheet to a semiconductor power module; and
forming a second bond layer at the lower main face of the core layer for bonding the hybrid bond sheet to a heat sink, wherein the core layer is subdivided into a plurality of core metal sections and core polymer sections which are formed side-by-side between the upper main face and the lower main face, and the plurality of core metal sections is being configured to enable a uniform heat transfer between the semiconductor power module and the heat sink and to reduce thermal stress at interfaces between the hybrid bond sheet and the heat sink.
